(19) United States
(12) Patent Application Publication
(10) Pub. No.: US 2026/0238931 A1
(43) Pub. Date: Aug. 13, 2026

(54) MEMS WITH SYNCHRONOUS MOVABLE ELEMENTS

(71) Applicant: FRAUNHOFER-GESELLSCHAFT ZUR FOERDERUNG DER ANGEWANDTEN FORSCHUNG E.V., Muenchen (DE)

(72) Inventors: Klaus SCHIMMANZ, Dresden (DE); Michael STOLZ, Dresden (DE); Bert KAISER, Dresden (DE)

(21) Appl. No.: 19/637,091

(22) Filed: Apr. 2, 2026

Related U.S. Application Data
(63) Continuation of application No. PCT/EP2024/077630, filed on Oct. 1, 2024.

(30) Foreign Application Priority Data
Oct. 5, 2023 (DE) 102023209765.6

(51) Int. Cl. H04R 19/02; B81B 3/00

(52) U.S. Cl. CPC H04R 19/02; B81B 3/0056; B81B 2201/0257; H04R 2201/003

(57) ABSTRACT

A MEMS includes a substrate having a cavity disposed in the substrate and a plurality of movable elements disposed in the cavity that are configured to interact with a fluid disposed in the cavity, wherein a movement of the fluid and a movement of the movable elements are causally related. The plurality of movable elements are formed to be electrically active and are electrically connected in parallel to each other via a respective electrical conduction path with a common signal reference. The MEMS is configured to adapt run time differences between the common signal reference and the conduction paths of different movable elements to each other in order to synchronize movements of the movable elements, said movements having been generated by an electrical signal provided at the signal reference, and/or in order to synchronize electrical signals generated by the movable elements through the movement at the location of the signal reference.

### CROSS-REFERENCES TO RELATED APPLICATIONS

This application is a continuation of copending International Application No. PCT/EP2024/077630, filed Oct. 1, 2024, which is incorporated herein by reference in its entirety, and additionally claims priority from German Application No. EP 10 2023 209 765.6, filed Oct. 5, 2023, which is incorporated herein by reference in its entirety.

### BACKGROUND OF THE INVENTION

The present invention relates to a MEMS with synchronous movable elements and a method for operating a MEMS. The present invention relates, in particular, to a MEMS with electrically synchronous fins or movable elements.

In MEMS for moving a fluid, for example in sounders, and in MEMS for detecting or sensing a movement in a fluid, for example in the form of a microphone, embodiments exist in which movable elements for moving or being moved are connected in parallel. For an advantageous operation, it is therefore desirable to avoid distortions and deviations between movements.

From WO 2021/144400 A1, a MEMS sound transducer is known in which the electrodes for controlling the lamellae are connected in parallel. FIG. 11 of WO 2021/144400 A1 illustrates an electrical contacting of a MEMS loudspeaker with an oscillatable membrane based on individual piezoceramics, which is preferred therein. FIG. 11A is a top view and FIG. 11B is a side view of the MEMS loudspeaker. Individual lamellae and vertical sections, respectively, are controlled in parallel via electrode pads, with U-shaped spacers being present on each side of the lamellae and creating a mechanical and electrical connection to the next lamella.

However, such systems have disadvantages with respect to distortions in the generated signals.

MEMS with good signal properties in the actuator and/or sensor field would thus be desirable.

A core idea of the present invention is based on the finding that at least part of a deviating behavior between movable elements stems from the fact that the same are connected with a common signal reference, for example a signal sink or a signal source, and a collection point, respectively, and that there are different run time differences between the signal reference and the respective movable element. According to the invention, it was found that a compensation and a balancing, respectively, of the run time differences in order to synchronize the movement of the movable elements or in order to synchronize the generated electrical signals at the location of the signal reference leads to good signal properties of the generated signals, both in an actuator operation and in a sensor operation.

### SUMMARY

According to an embodiment, a MEMS may have a substrate having a cavity disposed in the substrate; a plurality of movable elements disposed in the cavity that are configured to interact with a fluid disposed in the cavity, wherein a movement of the fluid and a movement of the movable elements are causally related; wherein the plurality of movable elements are formed to be electrically active and are electrically connected in parallel to each other via a respective electrical conduction path with a common signal reference; wherein the MEMS is configured to adapt run time differences between the common signal reference, on the one hand, and the conduction paths of different movable elements, on the other hand, to each other in order to synchronize movements of the movable elements, said movements having been generated by an electrical signal provided at the signal reference, and/or in order to synchronize electrical signals generated by the movable elements through the movement at the location of the signal reference.

According to another embodiment, a method for operating a MEMS having a substrate, having a cavity disposed in the substrate and having a plurality of movable elements disposed in the cavity and formed to be active may have the steps of: moving the plurality of movable elements disposed in the cavity such that the movable elements interact with a fluid disposed in the cavity so that a movement of the fluid and a movement of the movable elements are causally related; such that the plurality of movable elements are electrically connected in parallel to each other via respective electrical conduction path with a common signal reference; and such that run time differences between the common signal reference, on the one hand, and the conduction paths of different movable elements, on the other hand, are adapted to each other in order to synchronize movements of the movable elements, said movements having been generated by an electrical signal provided at the signal reference, and/or in order to synchronize electrical signals generated by the movable elements through the movement at the location of the signal reference.

According to an embodiment, a MEMS includes a substrate having a cavity disposed in the substrate. The MEMS includes a plurality of movable elements disposed in the cavity that are configured to interact with a fluid disposed in the cavity, wherein a movement of the fluid and a movement of the movable elements are causally related. The plurality of movable elements are formed to be electrically active and are electrically connected in parallel to each other via a respective electrical conduction path with a common signal reference. The MEMS is configured to adapt run time differences between the common signal reference, on the one hand, and the conduction paths of different movable elements, on the other hand, to each other in order to synchronize movements of the movable elements, said movements having been generated by an electrical signal provided at the signal reference, and/or in order to synchronize electrical signals generated by the movable elements through the movement at the location of the signal reference.

According to an embodiment, a method for operating a MEMS having a substrate and a cavity disposed in the substrate and a plurality of movable elements disposed in the cavity and formed to be active includes moving the plurality of movable elements disposed in the cavity such that the movable elements interact with a fluid disposed in the cavity so that a movement of the fluid and a movement of the movable elements are causally related. The method is executed such that the plurality of movable elements are electrically connected in parallel to each other via a respective electrical conduction path with a common signal reference. Run time differences between the common signal reference, on the one hand, and the conduction paths of different movable elements, on the other hand, are adapted to each other in order to synchronize movements of the movable elements, said movements having been generated by an electrical signal provided at the signal reference, and/or in order to synchronize electrical signals generated by the movable elements through the movement at the location of the signal reference.

### BRIEF DESCRIPTION OF THE DRAWINGS

Embodiments of the present invention will be detailed subsequently referring to the appended drawings, in which:

FIG. 1 shows a schematic sectional side view of a MEMS according to an embodiment;

FIG. 2a shows a schematic top view of sections of conduction paths according to embodiments;

FIG. 2b shows a schematic representation of an embodiment to adjust the electrical impedances of conduction paths to each other;

FIG. 2c shows a schematic block circuit diagram of a MEMS according to an embodiment in which the signal reference of a MEMS is coupled to a signal source for providing a signal voltage;

FIG. 3 shows a schematic equivalent circuit diagram of a MEMS according to an embodiment;

FIG. 4 shows a schematic flow diagram of a method according to an embodiment.

### DETAILED DESCRIPTION OF THE INVENTION

Before discussing embodiments of the present invention in detail below with reference to the drawings, it should be noted that elements, objects, and/or structures that are identical or functionally equivalent or that have equivalent effects are provided with the same reference numerals in the different figures so that the description of these elements presented in the different embodiments is interchangeable or can be applied among one another.

Embodiments described below are described in connection with a multitude of details. However, embodiments can also be implemented without these detailed features. Furthermore, for a better understanding, embodiments are described using block circuit diagrams instead of a detail representation. Furthermore, details and/or features of individual embodiments may easily be combined with each other, unless explicitly stated to the contrary.

The following embodiments relate to micro-electromechanical systems, MEMS, in which an actuator and/or sensor operation is provided. In the case of an actuator operation, forces may be generated using electrical signals in order to deflect movable elements. Examples thereof are described in DE 10 2017 206 766 A1 and WO 2022/117197 A1 which are particularly suited for the use of the present invention, without limiting the invention. In this regard, the references cited are incorporated into the present patent application in their entirety.

Movable elements of a MEMS may move in parallel to a substrate plane or a wafer surface, which is also referred to as an in-plane movement. Alternatively or additionally, movable elements may also move perpendicular hereto, i.e., out of plane, which may be implemented in an independent and in a combinational manner within the framework of the invention described herein.

In an actuator operation, for example, piezoelectric, electrostatic, electrodynamic, thermomechanical or other actuators may be used to convert an electrical signal into a positioning force for the movable element. Examples of actuators are, for example, pumps or sounders, and loudspeakers, respectively. In a sensor operation, for example, a force acting on the respective movable element and causing a deflection of the movable element may be converted into an electrical signal. Examples hereof are, for example, microphones or pressure sensors.

Since MEMS typically have low travel ranges when compared to macroscopic assemblies, there is sometimes a tendency to use multiple movable elements to generate corresponding signal amplitudes or effective forces. In an actuator operation, the movable elements may, for example, be connected in parallel to each other and may be driven together. In the case of a sensor operation, the movable elements may also be connected in parallel to each other and may be evaluated together.

Embodiments of the present invention in particular relate to MEMS having actively movable elements that are mechanically and electrically connected in parallel and have different track resistances and impedances, respectively, of the signal line due to differing distances to the voltage source or signal sink. This may lead to the signal voltage amplitude reaching the actively movable elements with a delay in the course of an exponential function, in which case an RC low-pass behavior should be noted.

The actively movable elements having the shortest distance to the voltage source in the circuit reach the predefined signal voltage first. The other movable elements that are disposed further away follow the signal voltage with a time delay corresponding to their respective position. The time offset described and also the deviating quality of the signal voltage when controlling the individual active devices may cause an undesired behavior of said devices, such as a reduced transduction or asynchrony.

In a sounder, such as a micro-loudspeaker, this may result in a reduced deflection of individual elements and, thus, in a low sound release or a phase offset, which, in turn, may result in undesired artifacts and tone deviations and/or cause a limitation in the function of devices, for example by means of a pull-in in electrostatic systems. Thus, for example, actuators that are closer to the signal voltage source may pull in more frequently. Due to the abrupt increase in capacitance, the voltage at the actively movable element is reduced. Furthermore, varactors also increase the delay time, which becomes more pronounced the greater the change in the electrical capacitance of the drive unit caused by the control.

Such effects occur in actively movable elements, for example in MEMS micro-loudspeakers, MEMS pumps, MEMS valves, MEMS varactors, and/or MEMS ultrasound devices. In addition to the actuators described, corresponding sensors can also be improved with the embodiments described herein. Embodiments enable movable elements in a MEMS transducer to work synchronously.

Embodiments overcome the disadvantage of currently known solutions consisting in the fact that actuators connected in parallel have different conduction lengths and unadjusted conduction resistances, respectively, and/or unadjusted conduction impedances when compared to the signal source or signal sink. Actuators having the shortest conduction lengths and the smallest conduction resistance, respectively, currently reach the predefined signal voltage first. According to embodiments, it is possible to at least approximate a state in which the same signal voltage is applied to all active elements at the same time and the signals are obtained from all active elements at a signal reference at the same time, respectively.

Embodiments of the present invention are directed to providing a MEMS transducer having a multitude of synchronously working elements. This reduces or prevents a delay of the signal voltage at the transducer elements and/or a delayed arrival at a signal reference and an undesired behavior, such as a pull-in of the elements that are closer to the signal voltage source.

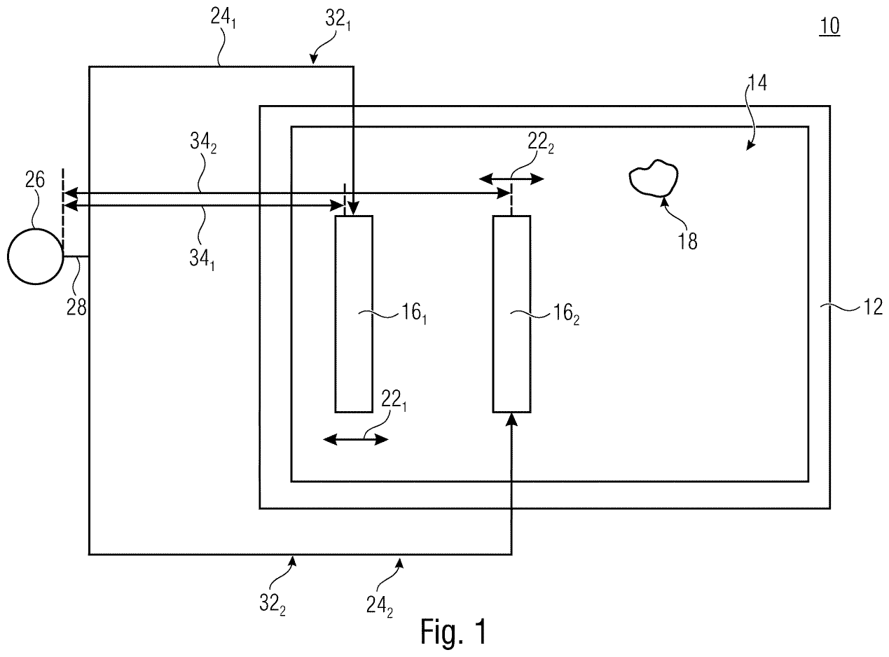

FIG. 1 shows a schematic sectional side view of a MEMS 10 according to an embodiment. In other configurations of embodiments described herein, the discussions also easily apply to a plan view of a MEMS. The MEMS 10 includes a substrate 12 having a cavity 14 disposed in the substrate 12. The substrate 12 may be formed to be single-layer or multi-layer, for example, by etching out the cavity 14 and/or by connecting multiple wafers with each other, for example, by using a bonding process. The substrate 12 may, for example, comprise a semiconductor material, for example including a monocrystalline or polycrystalline silicon, although other MEMS-compatible semiconductor materials may easily be applicable.

Electrical connections in the substrate 12 and/or the MEMS 10 may be obtained by dopings in the semiconductor materials and/or by using other conducting materials, such as metal materials.

The MEMS 10 includes a plurality of movable elements 16₁ and 16₂ disposed in the cavity 14, wherein the number of movable elements may easily be greater than 2, for example at least 3, at least 5, at least 10, or more.

The movable elements 16₁ and 16₂ are configured to interact with a fluid 18 disposed in the cavity, wherein a movement of the fluid 18 and a movement 22₁ of the movable element 16₁ and a movement 22₂ of the movable element 16₂ are causally related. Thus, for example, a movement of the fluid 18 may lead to the movements 22₁ and 22₂, for example, when the MEMS 10 is operated as a sensor. Alternatively or additionally, an active generation of the movements 22₁ and 22₂, for example using electrical signals, may lead to a movement of the fluid 18, for example by using the MEMS 10 as an actuator, for example as a sounder.

The movable elements 16₁ and 16₂ are formed to be active and are electrically connected in parallel to each other via a conduction path 24₁, 24₂ with a common signal reference 26. The signal reference 26 may be, but does not have to be an active circuit for generating and/or providing or for receiving and/or evaluating electrical signals. The signal reference 26 may also include a coupling point and a junction point, respectively, or an interface for contacting an external circuit for such purposes. The signal reference 26 may, for example, be or include a current source or a voltage source or may be coupled thereto to supply an electrical signal to the movable element 16₁ via the conduction path 24₁ and an electrical signal to the movable element 16₂ via the conduction path 24₂. The conduction paths 24₁ and 24₂ may optionally comprise a common portion 28, but may also be connected in parallel to each other directly at the signal reference 26.

Run times 32₁ and 32₂ of the conduction path 24₁ and the conduction path 24₂, respectively, may be influenced by multiple parameters. One such parameter is, for example, a conduction length, another parameter is an ohmic resistance, which, in turn, may be influenced by the conduction length, but also by a conduction cross-section. Another parameter is capacitive couplings that may also result from a periphery of the respective conduction path 24₁ and/or 24₂. The MEMS 10 is configured to adapt the run time differences 32₁ between the signal reference 26 and the movable element 16₁, on the one hand, and between the signal reference 26 and the movable element 16₂ to each other. In other words, measures may be taken in the MEMS 10 to adapt the run times 32₁ and 32₂ to each other, thereby keeping run time differences between the run times 32₁ and 32₂ small. In an actuator operation, this may achieve synchronization of an electrical signal provided at the signal reference 26 for generating the movements 22₁ and 22₂ of the movable elements 16₁ and 16₂. In an alternatively or additionally implemented sensor operation, this may achieve synchronization, at the location of the signal reference 26, of electrical signals generated by the movable elements 16₁ and 16₂ through the movement 22₁ and 22₂, respectively.

The movements 22₁ and 22₂ may be disposed in the same or along mutually differing spatial directions, wherein, in particular, a parallel alignment of the movements 22₁ and 22₂ is advantageous. The movements 22₁ and 22₂ may be disposed in plane and/or out of plane. Furthermore, the cavity 14 may be, but does not have to be sealed off from surroundings of the substrate 12. Embodiments provide that openings in the substrate 12 connect the cavity 14 with the surroundings and that the fluid 18 may stream into the cavity 14 and/or out of the cavity 14 through such openings.

According to embodiments, the movable elements are disposed at mutually differing distances 34₁, 34₂ to the signal reference 26 in the MEMS. This may, for example, result from the fact that the signal reference 26 is disposed at a specific location in the MEMS 10 or may be connectable to the MEMS 10 at a specific location, for example in a case where the signal reference 26 includes an external circuit that may be coupled to the MEMS 10. Movable elements 16₁ and 16₂ positioned at different locations in the MEMS 10 may have mutually differing distances to said location. In known circuits, this may lead to a possible use of conduction paths 24₁ and 24₂ with different run times 32₁ and 32₂, which is, however, addressed by embodiments described herein. To this end, embodiments provide different possibilities that may be implemented individually, but also in combination with each other.

For example, embodiments provide that the conduction paths 24₁ and 24₂ comprise a substantially equal electrical junction characteristic of the movable elements 16₁ and 16₂ to the signal reference 26. Such a junction characteristic may, for example, mean or include an electric conductivity and/or an electrical impedance, i.e., the conduction paths 24₁ and/or 24₂ may be configured such that there is a junction characteristic that is substantially or as precisely as possible matching, for example an approximately equal electrical conductivity and/or an approximately equal electrical impedance. Deviations from an exact match are easily possible within the framework of embodiments described herein, for example within a tolerance range of ±20%, ±10%, or ±5%, or advantageously less.

When compared to a theoretical initial state in which the movable elements 16₁ and 16₂ have mutually differing distances to the signal reference 26, at least one of the conduction paths 24₁ and 24₂ may be modified. Thus, for adjusting the electrical junction characteristic, at least a conduction-path-specific meandering of a course of at least one of the conduction paths may be provided. Alternatively or additionally, a conduction-path-specific cross-section modification may be provided. The same may relate to the entire conduction path or simply to portions thereof. Thus, a local reduction of the conduction cross-section may generate a local increase of a conduction capacitance and/or a conduction track resistance. Alternatively or additionally, one of the conduction paths 24₁ or 24₂ may be provided with a smaller or an increased conduction cross-section when compared to the other conduction path. Alternatively or in addition to these measures, the conduction paths may include a conduction-path-specific capacitive coupling between the conduction path and the substrate in order to adjust the electrical junction characteristic. Such a coupling may, for example, exist towards adjacent layers or wafers, for example towards a cap wafer and/or a bottom wafer capable of limiting a cavity 14 provided in a device wafer.

According to embodiments, the conduction paths 24₁ and 24₂ may be formed such that the same have a substantially equal electrical conductivity. This may, for example, be achieved by forming shorter conduction paths having a larger cross-section than longer conduction paths. Alternatively or additionally, this may also be achieved by extending conduction paths for movable elements that are disposed closer to the signal reference 26, such as the conduction path 24₁, by means of additional conduction lengths so that the conduction paths 24₁ and 24₂ have an adapted conduction length. The same may possibly be at least approximately matching, but in view of other measures, such as additional modifications of the conduction cross-section or the like, this is not necessary, since these measures are, individually or in combination, directed towards adapting the run time differences 32₁ und 32₂ to each other.

According to an embodiment, the movable elements 16₁ and 16₂ have mutually differing distances to the signal reference 26, but at the same time have a substantially equal conduction length.

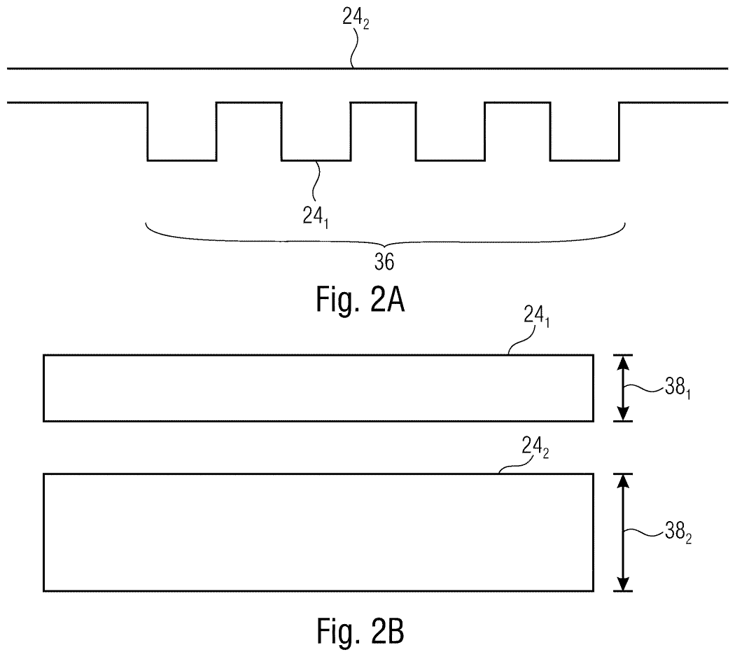

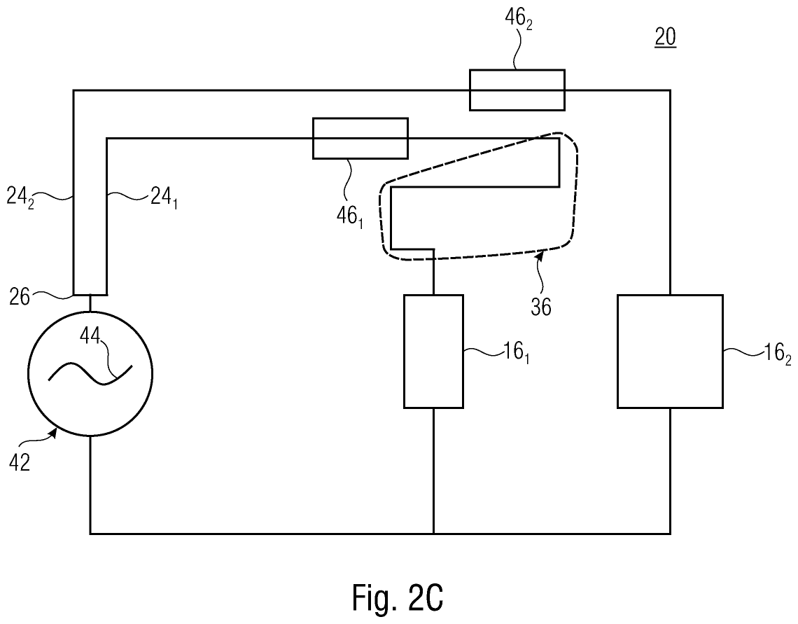

FIG. 2a shows a schematic top view of sections of the conduction paths 24₁ and 24₂, as they may be used in the MEMS 10, for example. With reference to FIG. 1, the movable element 16₁, which is connected to the signal reference 26 via the conduction path 24₁, is disposed with a shorter distance 34₁ than the movable element 16₂, which is disposed with the distance 34₂. The conduction path 24₁ may comprise an additional conduction path portion 36 in order to adapt a respective length of the conduction paths 24₁ and 24₂ to each other. The additional portion 36 may advantageously be disposed to be meandering (or meandered), since inductivities may hereby be kept low. Additional portions 36 may be disposed at one or more positions along the conduction path 24₁. This does not in principle exclude additional portions 36 also in the conduction path 24₂. However, it should be noted that within the framework of embodiments described herein, it is assumed, for the sake of simplicity, that the conduction paths of movable elements that are disposed closer to the signal reference 26 are extended in order to achieve an adaptation of the conduction path lengths. Due to layout-specific circumstances in the MEMS 10, it may, however, also be the case that movable elements that are disposed closer to the signal reference 26 are to be connected to the signal reference 26 via a relatively longer conduction path length so that an adaptation may then be performed for the conduction path that has a shorter direct distance, but a longer conduction length.

According to an embodiment, the movable elements 16₁ and 16₂ may be disposed at mutually differing distances 34₁ and 34₂ to the signal reference 26 in the MEMS 10. However, the conduction paths 24₁ and 24₂ may have a substantially equal conduction length, such as within a tolerance range of ±20%, ±10%, ±5%, or less. The conduction paths 24₁ and 24₂ may each comprise a respective possibly meandering conduction path portion, wherein the different additional and possibly meandering conduction path portions have a first electrical impedance and a second electrical impedance, respectively, wherein, through the additional conduction path portions, an overall obtained impedance of the first conduction path 24₁ and an overall obtained impedance of the second conduction path 24₂ as a whole substantially match. This means that a sum impedance of an actual conduction path length and additional portions leads to a substantially matching conduction path impedance within the tolerances listed, wherein additional portions to this end are optional and may possibly only be provided for those conduction paths that are significantly shorter than other conduction paths so that even at least one of the conduction paths in the MEMS 10 may remain without additional portions.

This means that the impedance adjustment may be formed differently in different conduction path portions using meandering, but that the remaining path portions also have mutually differing impedances due to the different lengths so that the sum of the impedances from meandering and remaining path length may match the other conduction paths as a whole.

According to embodiments, it is possible to provide that the electrical conduction paths have a substantially equal electrical impedance. According to an embodiment hereof, in different conduction paths, a path-specific cross-section modification of at least one conduction path and/or a path-specifically meandering conductor trace portion may be provided in order to adapt the electrical impedance.

In FIG. 2b, an option of adapting the respective electric impedance of the conduction paths 24₁ and 24₂ to each other is shown. Thus, for example, the movable element 16₁ that is disposed relatively closer may be connected to the signal reference 26 via the conduction path 24₁ having a width 38₁, while the movable element 16₂ that is disposed relatively further away may be electrically connected to the signal reference 26 via the conduction path 24₂ having a width 38₂. This may be particularly suitable for MEMS structures in which a layer thickness of electrical traces in a MEMS wafer are formed to be equal. Alternatively or additionally, the widths 38₁ and 38₂ may also relate to another spatial direction, such as a layer thickness, wherein combinations to this end are also possible. Each spatial direction allows setting a conduction trace cross-section individually or in combination with another spatial direction.

In addition to a path-specific cross-section modification and a path-specific conduction cross-section, respectively, as described above, a path-specifically meandering conductor trace portion may be disposed. Different additional conduction path portions may differ with respect to a number of meanderings, a length of the meanderings and/or a shape and spatial density of the meanderings, respectively. Alternatively or additionally, a path-specific capacitive coupling with the substrate may be disposed in order to obtain a substantially equal electrical impedance between different conduction paths.

FIG. 2c shows a schematic block circuit diagram of a MEMS 20 according to an embodiment in which the signal reference 26 is coupled with a signal source 42 for providing a signal voltage 44. The signal voltage 42 may be part of the MEMS 20 or may be provided as an external component. A junction characteristic 46₁ of the conduction path 24₁ may at least approximately be adapted to a junction characteristic 46₂ of the conduction path 24₂ by disposing the portion 36 in the conduction path 24₁.

In other words, FIG. 2c shows a system with equal control characteristics for the electrodes to be connected in parallel, i.e., the movable elements 16₁, 16₂.

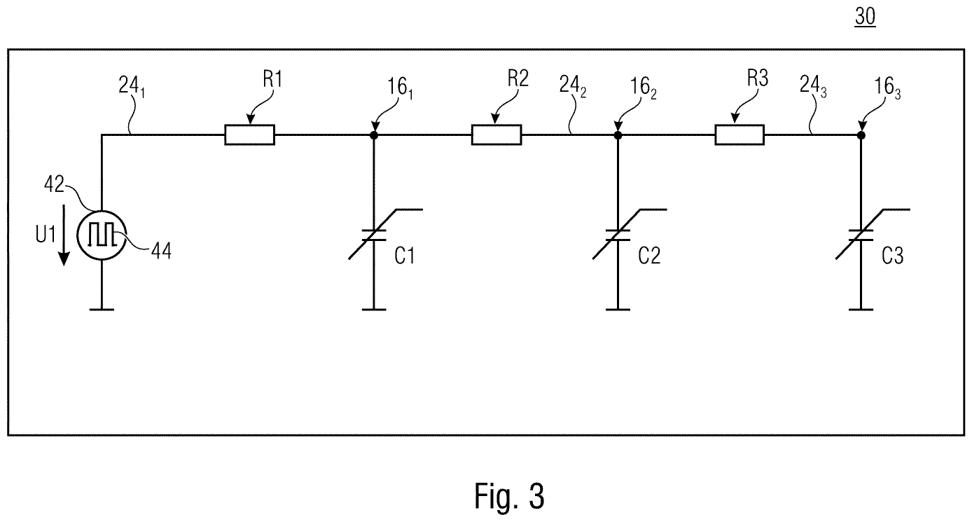

FIG. 3 shows a schematic equivalent circuit diagram of a MEMS 30 according to an embodiment. The MEMS 30 has, by way of example, a signal source 42 that may provide the signal reference 26 of the MEMS 10 or that is at least coupled thereto. In other words, for coupling with a signal source, such as the signal source 42, the signal reference 26 of the MEMS 10 may be configured for controlling the movable elements 16₁ to 16₃. The movable elements 16₁ to 16₃ may be connected to each other in parallel so that a respective track resistance R1, R2 may have at least part of an overall track resistance of a subsequent conduction path 24₂ and 24₃, respectively. For example, the conduction path 24₂ may include the resistances R1 and R2, and the conduction path 24₃ may additionally include the track resistance R3. It is also shown that, for different movable elements 16₁, 16₂, and 16₃, different capacitive couplings C1, C2 as well as C3 may be operative, wherein, in particular, the capacitances C1 to C3 may have effects depending on a signal voltage 44 of the signal source 42, such as a frequency hereof. It becomes clear that by providing the measures described herein, either individually or in combination, an adaptation in the behavior of the movable elements 16₁ to 16₃ may be achieved, which is advantageous.

According to an embodiment and with reference to a layered structure of MEMS as described herein, a respective conduction path may comprise a capacitive coupling to at least one layer of the substrate 12 contributing to a conduction-path-specific impedance. The capacitive couplings may be adjusted individually in order to adapt a respective acting impedance in different conduction paths to each other. This may, for example, be implemented by applying conductor traces that may have equal lengths and/or equal cross-sections and by disposing the same on isolators of different types or dielectric layers that may be have mutually differing dielectric constants. Hereby, mutually differing capacitive couplings with the substrate may be obtained. Alternatively or additionally, the capacitive coupling may also be set by mutually differing shapings, such as a size of an area which becomes capacitive. This does not exclude combinations with respect to the conductor trace cross-section and/or possible meanderings.

According to an embodiment, a MEMS described herein, such as the MEMS 10 and/or 30, is configured to be a sensor or an actuator. Possible actuators are sounders that may, for example, be operated in an infrasound, acoustic and/or ultrasound range, such as loudspeakers. The movable elements 16 may be configured for the synchronized generation of a sound wave in the fluid.

In other words, FIG. 3 shows a MEMS transducer with electrodes that appear to be connected in parallel, but that are actually connected in series. The state illustrated herein may easily be applied to elements that are actually connected in parallel according to embodiments.

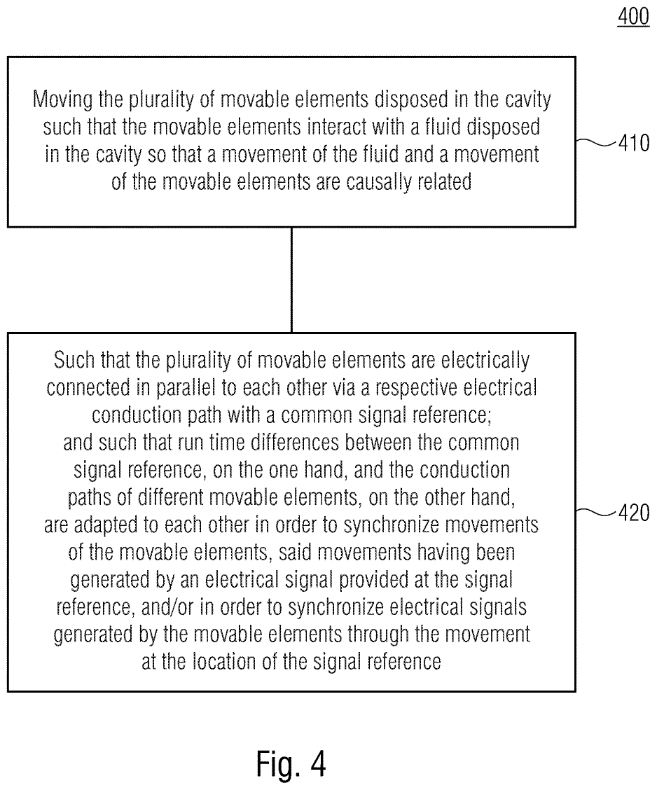

FIG. 4 shows a schematic flow diagram of a method 400 according to an embodiment. A step 410 includes moving of the plurality of movable elements of a MEMS disposed in the cavity such that the movable elements interact with a fluid disposed in the cavity so that a movement of the fluid and a movement of the movable elements are causally related.

Features 420 of the method 400 cause the same to be executed such that the plurality of movable elements are electrically connected in parallel to each other via a respective electric conduction path with a common signal reference. The method is executed such that run time differences between the common signal reference, on the one hand, and the conduction paths of different movable elements, on the other hand, are adapted to each other in order to synchronize movements of the movable elements, said movements having been generated by an electrical signal provided at the signal reference, and/or in order to synchronize electrical signals generated by the movable elements through the movement at the location of the signal reference. The adapting may either be provided within the MEMS or may, for example, be implemented using an additional connection with a signal source or signal sink to be coupled with the MEMS externally.

Embodiments of the present invention solve the object of providing signals with a high quality, among other things, by means of a parallel connection of the MEMS transducer elements, i.e., movable elements, wherein each element has the same electrical junction characteristic, such as conduction lengths or the like, with respect to the energy source or energy sink. The feed traces may be made to be geometrically specific to the active elements, in correspondence to their conductivity, which also includes the parasitic impedance.

Embodiments of the present invention relate to MEMS which may be characterized by a MEMS transducer structure having several elements, wherein all active elements of the transducer are electrically connected to each other in such a way that the terminals of the individual elements of the same kind are connected with a pole of the signal source via the same conduction lengths and impedances, respectively. Here, “of the same kind” means a connection with an equal potential.

According to some embodiments, the impedance is set via the conduction length by meandering. According to alternative or additional embodiments, the impedance is set by a cross-section modification, which may be implemented by means of an etching from the top or from the bottom, such as in the form of an “indentation”. According to further embodiments, which can be used alternatively or additionally, the impedance may also be introduced as a capacitive load through the connection with the cap wafer.

Although some aspects have been described in the context of an apparatus, it is understood that these aspects also represent a description of the corresponding method so that a block or component of an apparatus is also to be understood to be a corresponding method step or a feature of a method step. In analogy, aspects described in connection with or as a method step also represent a description of a corresponding block or detail or feature of a corresponding apparatus.

While this invention has been described in terms of several embodiments, there are alterations, permutations, and equivalents which fall within the scope of this invention. It should also be noted that there are many alternative ways of implementing the methods and compositions of the present invention. It is therefore intended that the following appended claims be interpreted as including all such alterations, permutations and equivalents as fall within the true spirit and scope of the present invention.

1. A MEMS, comprising:
a substrate comprising a cavity disposed in the substrate;
a plurality of movable elements disposed in the cavity that are configured to interact with a fluid disposed in the cavity, wherein a movement of the fluid and a movement of the movable elements are causally related;
wherein the plurality of movable elements are formed to be electrically active and are electrically connected in parallel to each other via a respective electrical conduction path with a common signal reference;
wherein the MEMS is configured to adapt run time differences between the common signal reference, on the one hand, and the conduction paths of different movable elements, on the other hand, to each other in order to synchronize movements of the movable elements, said movements having been generated by an electrical signal provided at the signal reference, and/or in order to synchronize electrical signals generated by the movable elements through the movement at the location of the signal reference.

2. The MEMS according to claim 1, wherein the movable elements are disposed at mutually differing distances to the signal reference in the MEMS.

3. The MEMS according to claim 1, wherein the conduction paths comprise a substantially equal electrical junction characteristic of the movable elements to the signal reference.

4. The MEMS according to claim 3, wherein the electrical junction characteristic comprises an electrical conductivity and/or an electrical impedance.

5. The MEMS according to claim 3, wherein the conduction paths, for adjusting the electrical junction characteristic, comprise at least one of a conduction-path-specific meandering of a course of conduction paths, a conduction-path-specific cross-section modification, and/or a conduction-path-specific capacitive coupling between the conduction path and the substrate.

6. The MEMS according to claim 1, wherein the conduction paths comprise a substantially equal electrical conductivity.

7. The MEMS according to claim 1, wherein the movable elements are disposed at mutually differing distances to the signal reference in the MEMS and wherein the conduction paths comprise substantially equal conduction lengths.

8. The MEMS according to claim 7, wherein a conductor trace of the first movable element disposed opposite of a second movable element comprising a shorter distance to the signal reference comprises an additional conduction path portion disposed to be meandering in order to adapt the lengths of the conduction paths.

9. The MEMS according to claim 1, wherein the movable elements are disposed at mutually differing distances to the signal reference in the MEMS and wherein the conduction paths comprise substantially equal conduction lengths; wherein at least a first conduction path comprises a first meandering conduction portion and a second conduction path comprises a second meandering conduction portion, wherein the first meandering conduction path portion comprises a first electrical impedance and the second meandering conduction path portion comprises a differing second electrical impedance and wherein a sum impedance of the first conduction path and a sum impedance of the second conduction path essentially match.

10. The MEMS according to claim 1, wherein the electrical conduction paths comprise a substantially equal electrical impedance.

11. The MEMS according to claim 10, wherein the different conduction paths comprise, for adapting the electrical impedance, a path-specific cross-section modification of at least one conduction path and/or a path-specifically meandering conductor trace portion and/or a path-specific capacitive coupling with the substrate.

12. The MEMS according to claim 1, wherein a respective conduction path comprises a capacitive coupling to at least one layer of the substrate contributing to a conduction-path-specific impedance, wherein the capacitive couplings are adjusted individually in order to adapt an acting impedance in different conduction paths to each other.

13. The MEMS according to claim 1, wherein the signal reference for coupling with a signal source is configured for controlling the movable elements.

14. The MEMS according to claim 13, comprising the signal source.

15. The MEMS according to claim 13, configured as a sounder, wherein the movable elements are configured for synchronously generating a soundwave in the fluid.

16. A method for operating a MEMS comprising a substrate, comprising a cavity disposed in the substrate and comprising a plurality of movable elements disposed in the cavity and formed to be active, the method comprising:
moving the plurality of movable elements disposed in the cavity such that the movable elements interact with a fluid disposed in the cavity so that a movement of the fluid and a movement of the movable elements are causally related;
such that the plurality of movable elements are electrically connected in parallel to each other via respective electrical conduction path with a common signal reference; and
such that run time differences between the common signal reference, on the one hand, and the conduction paths of different movable elements, on the other hand, are adapted to each other in order to synchronize movements of the movable elements, said movements having been generated by an electrical signal provided at the signal reference, and/or in order to synchronize electrical signals generated by the movable elements through the movement at the location of the signal reference.
